(19) United States
(12) Patent Application Publication
(10) Pub. No.: US 2011/0017498 A1
(43) Pub. Date: Jan. 27, 2011

(54) Photosensitive dielectric film

(75) Inventors: John M. Lauffer, Waverly, NY (US); Voya R. Markovich, Endwell, NY (US); Kostas I. Papathomas, Endicott, NY (US)

Correspondence Address: Mark Levy;HINMAN, HOWARD & KATTELL, LLP, 80 Exchange Street, P.O. Box 5250, BINGHAMTON, NY, 13901, US

(73) Assignee: Endicott Interconnect Technologies, Inc.

(21) Appl. No.: 12/460,975

(22) Filed: Jul. 27, 2009

(51) Int. Cl. H05K 1/09; C08J 3/28; B05D 5/12

(52) U.S. Cl. 174/256; 522/146; 427/126.2

(57) ABSTRACT

A photosensitive dielectric composition adapted for forming a dielectric film layer for use in a circuitized substrate is provided according to one embodiment of the invention, the composition including an epoxide bearing component including at least one polyepoxide resin curable by electromagnetic radiation, a cyanate ester, a flexibilizer, a nanostructured toughener, a photoinitiator in a predetermined amount by weight of the resin component, and a ceramic filler, the photosensitive dielectric composition forming the dielectric film layer having no solvent therein. In an alternative embodiment, a heat activated dielectric composition is provided which is curable by heat and includes an epoxide bearing component including at least one polyepoxide resin curable by heat, a cyanate ester, a flexibilizer, a nanostructured toughener, a heat activated curing agent for accelerating reaction of the cyanate ester and polyepoxide resin components, and a ceramic filler. Methods of making circuitized substrates from the above compositions are also provided.

### TECHNICAL FIELD

The present invention relates, in general, to circuitized substrates such as printed circuit boards (hereinafter also referred to simply as PCB's), chip carriers (interconnect structures designed to interconnect one or more semiconductor chips to a larger substrate such as a PCB) and the like, and particularly to dielectric materials suitable for use in such substrates so as to assure high density circuitization and other properties currently demanded for such products. Most particularly, it relates to such materials which are formed from compositions which are activated by electromagnetic energy and heat.

### BACKGROUND OF THE INVENTION

As known, circuitized substrates utilized in many of today's microelectronics products are of the organic type, meaning that the dielectric materials used in such substrates are organic in nature. Such organic substrates, especially the aforementioned chip carriers, have been and continue to be developed for many applications. These substrates are desired over the older technology ceramic substrates because of reduced cost and enhanced electrical performance. For example, an organic chip carrier may have one or move surface redistribution layers for redistributing electrical signals from one or more chips into a larger area so that the chips can properly interface with the underlying host printed circuit board.

The complexity of such circuitized substrates as defined herein has increased significantly over the past few years. For example, PCBs for mainframe computers may have as many as thirty-six layers of circuitry or more, with the complete stack having a thickness of as much as about 0.250 inch (250 mils). These boards are typically designed with three or five mil wide signal lines and twelve mil diameter thru-holes (defined more below). For increased circuit densification in many of today's products such as PCBs, chip carriers and the like, the industry desires to reduce signal lines to a width of two mils or less and thru-hole diameters to two mils or less. Many known commercial procedures are incapable of economically forming the dimensions desired by, the industry. Known processes for fabricating PCBs, chip carriers and the like typically comprise fabrication of separate inner-layer circuits (circuitized layers), which are formed by coating a photosensitive layer or film over a copper layer of a copper clad inner-layer base material. The photosensitive coating is imaged, developed and the exposed copper is etched to form conductor lines. After etching, the photosensitive film is stripped from the copper leaving the circuit pattern on the surface of the inner-layer base material. This processing is also referred to as photolithographic processing in the PCB art and further description is not deemed necessary.

After the formation of the individual inner-layer circuits, a multilayer stack is formed by preparing a lay-up of inner-layers, ground planes, power planes, etc., typically separated from each other by a dielectric pre-preg layer of material which typically comprises a layer of glass (typically fiberglass) cloth impregnated with a partially cured material, typically a known B-stage epoxy resin. The top and bottom outer layers of the stack usually comprise copper clad, glass-filled, epoxy planar substrates with the copper cladding comprising exterior surfaces of the stack. The stack is laminated to form a monolithic structure using heat and pressure to fully cure the B-stage resin. The stack so formed typically has metal (usually copper) cladding on both of its exterior surfaces. Exterior circuit layers (redistribution layers) are formed in the copper cladding using procedures similar to the procedures used to form the inner-layer circuits. For example, an organic chip carrier may have one or move surface redistribution layers for redistributing electrical signals from one or more chips into a larger area so that the chips can properly interface with the underlying host printed circuit board. A photosensitive film is applied to the copper cladding used to form such layers. The coating is exposed to patterned activating radiation and developed. An etchant is then used to remove copper bared by the development of the photosensitive film. Finally, the remaining photosensitive film is removed to provide the exterior circuit layers.

After construction, chips and/or other electrical components are mounted at appropriate locations on the exterior circuit layers of the multilayered stack, typically using solder mount pads to bond the components to the PCB. The components are often in electrical contact with the circuits within the structure through conductive “thru-holes” (see more below), as desired. The solder pads are typically formed by applying an organic solder mask coating over the exterior circuit layers. The solder mask may be applied by screen coating a liquid solder mask coating material over the surface of the exterior circuit layers using a screen having openings defining areas where solder mount pads are to be formed. Alternatively, a photosensitive solder mask may be coated onto the board and exposed and developed to yield an array of openings defining the pads. The openings are then coated with solder using processes known to the art such as wave soldering.

With presently known semiconductor chip input/output (I/O) counts increasing beyond the capability of peripheral lead devices and as both semiconductor chip and printed circuit board miniaturization demands increase, area array interconnects provided by such products as chip carriers have become the preferred means for providing large numbers of connections between semiconductor chips and the dielectric substrate of a host organic chip carrier, as well as between the resulting organic chip carrier and host PCB. Thus, it is highly desired in the microelectronics industry, as emphasized above, to provide circuit patterns of the highest density, meaning that the line widths and spacing must be as small as possible without allowing such adverse electrical problems as high impedance, line loss, etc. In addition, if the coefficient of thermal expansion (CTE) of the semiconductor chip, the organic chip carrier, and the PCB are substantially different from one another, industry standard semiconductor chip array interconnections to the organic chip carrier may be subject to high stress during thermal cycling operation. Similarly, the industry standard ball grid array (BGA) interconnections between the organic chip carrier (when solder balls are used for such connections) and PCB may also be subject to high stress during operation. Significant reliability concerns may then become manifest by failure of the connections or even failure of the integrity of the semiconductor chip (chip cracking). These reliability concerns significantly inhibit design flexibility. For example, semiconductor chip sizes may be limited or interconnect sizes, shapes and spacing may need to be customized in excess of industry standards in order to reduce such stresses. These limitations may in turn adversely limit the electrical performance advantages of the organic substrates (and thus the chip carrier and/or the PCB), in addition to likely adding undesirable cost to the final product. Typically, a semiconductor chip has a CTE of 2-3 parts per million per degree Celsius (ppm/degree C.) while a standard PCB usually has a greater CTE of about 17-20 ppm/degree C.

A particular reliability concern with respect to interconnect packages such as chip carriers is that the aforementioned surface redistribution layer(s), which interface(s) between the organic substrate and the semiconductor chip, may be susceptible to stresses resulting from thermal cycling of the organic substrate together with a chip which is soldered to the organic substrate's circuitry. Such stresses may result from a CTE differential between the surface redistribution layer(s) and the remainder (dielectric material) of the organic substrate. The ability of the surface redistribution layer to withstand such stresses depends on mechanical properties of the surface redistribution layer(s). If the redistribution layer cannot accommodate the thermal stresses, then the surface redistribution layer is susceptible to deterioration, such as cracking, which can cause failure of interconnections between the host organic chip carrier substrate and semiconductor chip positioned thereon and coupled thereto, as well as between the organic chip carrier and host PCB.

Yet another reliability concern is the proper formation and utilization of the aforementioned thru holes which form the interconnecting paths between the aforementioned conductive layers of each circuitized substrate product. These holes must be formed within the accommodating organic dielectric layer(s) in such a manner that these may be arranged in high density patterns if desired, of extremely small size (diameter) and also of necessary conductive thickness to assure an effective circuit path from one conductive layer to the other. By an effective path for such thru holes, as well as thru the circuit lines or traces which form part of the various circuit layers, is meant paths capable of providing consistent “high speed” signals, meaning signal speed capabilities within a frequency range of from about 3.0 to about 10.0 gigabits per second (GPS) and possibly even faster. As known, such high speed connections are subjected to various detrimental effects, e.g., signal deterioration (also referred to as signal attenuation), caused by the inherent characteristics of such known substrate circuitry wiring and possibly the dielectric material itself. In the particular case of signal deterioration, this effect is expressed in terms of either the “rise time” or the “fall time” of the signal's response to a step change. The deterioration of the signal can be quantified with the formula (Z₀ C)/2, where Z₀ is the transmission line characteristic impedance, and C is the amount of the connecting thru-hole capacitance (the thru-hole typically being plated with metal and/or including conductive paste therein). In a signal line (also referred to in the industry as a wire or trace) having a typical 50 ohm transmission line impedance, a plated thru hole having a capacitance of 4 pico-farads (pf) would represent a 100 pico-second (ps) rise-time (or fall time) degradation. This compares to 12.5 ps degradation with a 0.5 pf “buried via” type of thru hole. This difference is significant in systems which operate at 800 MHz or faster (not uncommon in today's microelectronics industry), where there are associated signal transition rates of 200 ps or faster.

Still further, another concern to circuitized substrate product manufacturers is flammability. This safety concern means the ability of the final product to become inflamed or burn, e.g., due to the presence of excessive heat and/or when operating under extremely high electrical loads. Understandably, potentially serious damages may arise should a circuitized substrate become inflamed or burn during operation. Such flammability concerns have long been recognized in the industry, which has in turn resulted in many dielectric materials possessing a flame retardant (“FR”) rating, e.g., “FR4.” In the case of multilayered substrates such as PCB's, this flammability rating is primarily determined by the thickness of the substrate's “core” structure, with the additional “build-up” layers then including flame retardant compositions. More specifically, some manufacturers have added halogen-containing additives such as bromine to the dielectric compositions of the “build-up” layers. Halogens such as bromine containing additives are known for retarding flame production under high heat conditions. However, there are environmental concerns with respect to such usage. Existing and/or proposed legislation in Europe and Japan, for example, now prohibit such materials.

It is thus understood that a critical aspect of the above circuitized substrate products is the dielectric material which forms the dielectric layers, of which there may be several, in each product. Prepreg laminates for conventional circuit boards are traditionally made up of a base reinforcing glass fabric impregnated with a resin, as stated above. Epoxy/glass laminates as used in some current products typically contain about 40% by weight fiber glass and 60% by weight epoxy resin, and typically have a relatively high dielectric constant (Er), sometimes higher than 4.0. Such a relatively high Er in turn causes electrical pulses (signals) in adjacent signal circuit lines to propagate less rapidly, resulting in excessive signal delay time. As newer computer systems become faster, system cycle times must become shorter. Delay time contributed by signal travel within the PCB's and other circuitized substrates used in such products will become very significant; hence the need for lower Er laminate materials exists. Many products are expected to require overall Er's of 2.8 or below. Such low Er's are impossible to obtain without new materials since the Er's of conventional FR4 epoxy and common fiber glass, as indicated above, are typically in the 4-6 range. The effective Er of such composite materials can usually be approximated by a simple weighted average of the Er of each individual component and its volume fraction contained in the composite.

As is known, “pure” fluoropolymers such as polytetrafluoroethylene (PTFE) have Er's of approximately 2.0. However, using such a material alone in construction of a circuit board laminate has sometimes proven impractical, due to generally poor mechanical properties and chemical inertness of this material. In a known example, an adhesive sheet (or “bond film”) material may be used to serve as adhesive layers in a variety of adhesive applications, such as in circuit board laminates, multi-chip modules, and in other electrical applications. In one such example, the adhesive sheet is described as being constructed from an expanded PTFE material and is filled with an inorganic filler. Formation is achieved by incorporating ceramic filler material into an aqueous dispersion of dispersion-produced PTFE. The filler in small particle form is ordinarily less than forty microns in size, and preferably less than fifteen microns. The filler is introduced prior to co-coagulation in an amount that will provide ten to sixty percent by weight filler in the PTFE, in relation to the final resin-impregnated composite. The filled PTFE dispersion is then co-coagulated, usually by rapid stirring. The coagulated filled PTFE is then added. The filled material is then lubricated with a common paste extrusion lubricant, such as mineral spirits or glycols, and then paste extruded. The extrudate is usually calendared, and then rapidly stretched to 1.2 times to 5000 times, preferably two to one hundred times, at a stretch rate of over ten percent at a temperature of between thirty-five degrees C. and 327 degrees C. The lubricant can be removed from the extrudate prior to stretching, if desired. The resulting expanded, porous filled PTFE is then imbibed with adhesive by dipping, calendaring, or doctor bladed on a varnish solution of about 2% to 70% adhesive in solvent. The wet composite is then affixed to a tenter frame, and subsequently B-staged at or about 165 degrees C. for one to three minutes. The resulting sheet adhesive typically consists of (a) 9 to 65 weight percent PTFE; (b) 9 to 60 weight percent inorganic filler, in the form of particulate; and (c) 5 to 60 weight percent adhesive imbibed within the porous structure of the filled PTFE web. One alternative to this approach is to use fluoropolymer as one of the components of a composite laminate material, such as the fiber in the reinforcing cloth. An example of this is the treated PTFE fabric prepreg produced by W. L. Gore and Associates, of Newark, Del. When this type of fabric is used to replace fiberglass in conventional epoxy/glass laminates, the Er drops to about 2.8. However, use of this fabric presents certain disadvantages. Because of the comparatively low modulus of pure PTFE, thin laminates made with these materials may not possess the desired rigidity and often require special handling. Also when laminates incorporating PTFE fabric are drilled, uncut PTFE fibers may protrude into the drilled holes and are difficult to remove. In order to obtain good plating adhesion, exposed PTFE surfaces must be treated using either an expensive, highly flammable chemical in a nitrogen atmosphere or by plasma processing, which must penetrate high aspect ratio through holes in order to obtain good plating adhesion. Certainly, one of the biggest disadvantages of PTFE fabric laminate is cost, not only the higher cost due to additional processing requirements and equipment modification, but also the considerable cost of purchasing the pre-preg material itself.

The following is a listing of issued patents which describe various products which may be similar to those defined herein. The listing thereof is not an admission that any are prior art to the instant invention, nor is it an admission that an exhaustive search has been completed.

### PATENT LISTING

U.S. Pat. No. 7,429,510—describes a method of forming what is defined as a “capacitive substrate” in which at least one capacitive dielectric layer of material is screen or ink jet printed onto a conductor layer and the substrate is thereafter processed further, including the addition of thru-holes to couple selected elements within the substrate to form at least two capacitors as internal elements of the substrate. Photo-imageable material is used to facilitate positioning of the capacitive dielectric being printed. The capacitive substrate may be incorporated within a larger circuitized substrate, e.g., to form an electrical assembly.

U.S. Pat. No. 7,270,845—defines a dielectric composition which is capable of forming a dielectric layer usable in circuitized substrates such as PCBs, chip carriers and the like. As such a layer, it includes a cured resin material and a predetermined percentage by weight of particulate fillers, while not including continuous fibers, semi-continuous fibers or the like as part thereof.

U.S. Pat. No. 7,078,816—defines a circuitized substrate comprising a first layer comprised of a dielectric material including a resin material including a predetermined quantity of particles therein and not including continuous fibers, semi-continuous fibers or the like as part thereof, and at least one circuitized layer positioned on the dielectric first layer. An electrical assembly and a method of making the substrate is also provided, as is a circuitized structure including the circuitized substrate in combination with other circuitized substrates having lesser dense thru-hole patterns.

U.S. Pat. No. 6,829,823—describes a method of making a multi-layered interconnect structure wherein first and second electrically conductive members are formed on first and second dielectric layers, respectively. The dielectric layers are formed on opposing surfaces of a thermally conductive layer. First and second electrically conductive layers are formed within the first dielectric layer. The second electrically conductive layer includes shielded signal conductors and is positioned between the first electrically conductive layer and the thermally conductive layer. A plated through hole (PTH) formed through the interconnect structure is electrically connected to one of the first and second electrically conductive members and to one of the shielded signal conductors. A third dielectric layer, formed on the first dielectric layer and on portions of the first electrically conductive members, substantially overlies the PTH and includes a high density interconnect layer for providing an electrical path from an electronic device to the shielded signal conductors.

U.S. Pat. No. 6,734,369—describes what is referred to as a “surface laminar circuit board” which includes an insulating layer, and a signal ground conductive layer disposed on an upper surface of the insulating layer. The conductive layer has a hole formed therein. A photosensitive dielectric layer is disposed on an upper surface of the signal ground conductive layer. The dielectric layer has a photo micro-via formed therein. A signal trace is disposed on the photosensitive dielectric layer, and is electrically coupled with the signal ground conductive layer by way of the photo micro-via. A conductive pad is provided, which has a majority thereof within an area defined by an outer periphery of the hole. The conductive pad is electrically coupled with the signal trace. A surface mounted component is mounted on the conductive pad.

U.S. Pat. No. 6,673,473—describes a method of constructing a multilayer electric apparatus, comprising the steps of first providing a set of dielectric layers and forming a set of conductive features and at least one fiducial location marking, in mutual reference to each other, on a first one of the dielectric layers. The dielectric layers are next joined together to form a “stack”, such that the first of the dielectric layers is interposed between others of the dielectric layers and the at least one fiducial marking is distinctly observable from outside of the “stack”. Finally, a “blind” via hole is drilled from the exterior of the “stack” to one of the conductive features of the first dielectric layer, referencing the drilling to the fiducial marking.

U.S. Pat. No. 6,534,245—describes where apertures in a circuit board or chip carrier are filled with a cured photosensitive dielectric material by substantially filling the apertures in the circuit board or chip carrier and applying a layer of a thickness to the circuit board or chip carrier with a positive photosensitive dielectric material, exposing the photosensitive dielectric material to actinic radiation in such a way as to leave material located in apertures unexposed to the radiation, baking the structure so as to harden the unexposed photosensitive dielectric material, and thereafter developing the exposed dielectric material in order to remove it, leaving behind cured photosensitive dielectric material in the apertures.

U.S. Pat. No. 6,495,239—describes a dielectric structure wherein two fully cured photo-imageable dielectric (or, simply, HD in this patent) layers of the structure are non-adhesively interfaced by a partially cured PID layer. The partially cured PID layer includes a power plane sandwiched between a first partially cured HD sheet and a second partially cured PID sheet. The fully cured PID layers each include an internal power plane, a plated via having a blind end conductively coupled to the internal power plane, and a plated via passing through the fully cured PID layer. The dielectric structure may further include a first PID film partially cured and non-adhesively coupled to one of the fully cured PID layers. The dielectric structure may further include a second HD film partially cured and non-adhesively coupled to the other fully cured HD layer.

U.S. Pat. No. 6,391,210—describes a circuit board having a structure including a permanent photo-imageable dielectric material suitable for fabrication of vias both by laser ablation, plasma ablation, or mechanical drilling techniques and by photo-imaging techniques. A process is also disclosed for the manufacture of a multi-level circuit on a substrate having a first-level circuitry pattern on at least one side. The process comprises applying a permanent photo-imageable dielectric over the first-level circuitry pattern; exposing the permanent photo-imageable dielectric to radiation, laminating a conductive metal layer to the dielectric, making holes in the conductive metal layer and dielectric by mechanical drilling or by laser or plasma ablation, and making a second-level circuitry pattern and filling the holes with a conductive material to electrically connect the first and second layers of circuitry. A further process is claimed for designing a multi-level circuit board product comprising making a prototype having the above structure in which the holes are manufactured by mechanical drilling or by laser or plasma ablation, evaluating the prototype, and then manufacturing a commercial circuit board having essentially the same structure and materials of construction as the prototype, but wherein the holes are manufactured by photo-imaging techniques.

U.S. Pat. No. 6,338,937—describes a method of producing a printed circuit board which comprises the steps of preparing a photosensitive resin layer, pressing this photosensitive resin layer, exposing this pressed photosensitive resin layer to light by using a exposure mask on which a predetermined pattern is formed, and thereafter developing the exposed photosensitive resin layer.

U.S. Pat. No. 6,323,436—describes the preparation of PCBs by initially impregnating a non-woven aramid chopped fiber mat or a thermoplastic liquid crystalline polymer (LCP) paper instead of the reinforcement typically used in the electronics industry, described in this patent as a woven glass fabric. The aramid reinforcement is comprised of a random (in-plane) oriented mat of p-aramid (poly (p-phenylene terephthalamide)) fibers comprised of Kevlar (Kevlar is a trademark of E.I. DuPont de Nemours and Company), and has a dielectric constant of 4.0 as compared to 6.1 for standard E-glass cloth. The lower permittivity of the non-woven aramid reinforcement provides for faster signal propagation, allowing increased wiring density and less crosstalk, which becomes increasingly important for high I/O chips and miniaturization. Since the p-aramid fibers are transversely isotropic and have an axial CTE of about −3 to about −6 ppm/degree C. when combined with a thermosetting resin, the final composite described in this patent is said to possess a CTE which can be controlled and adjusted to match that of silicon or semiconductor chips in the range of about 3 to about 10 ppm/degree C. The thermoplastic liquid crystal polymer paper is a material called Vecrus (Vecrus is a trademark of Hoechst Celanese Corp.). LCP paper uses the company's Vectra polymer (Vectra also being a trademark of Hoechst Celanese Corp.). According to this patent, it has a dielectric constant of 3.25 and a dissipation factor of 0.024 at 60 Hz. The polymer paper has a UL94-V0 rating and an in-plane CTE of less than 10 ppm/degree C. The alleged advantages of this material over the aramid mat are the lower dielectric constant and very low moisture absorption, less than 0.02%. The non-woven aramid or LCP paper is used in conjunction with a thermosetting resin to form the final composite substrate. Examples of thermosetting resins described as being useful in this patent include epoxy, cyanate ester, bismaleimide, bismaleimide-triazine, maleimide or combinations thereof. The resin-impregnated low CTE reinforcement is then partially cured to a “B”-stage to form the prepreg, and then the prepreg is cut, stacked, and laminated to form a subcomposite with exterior copper sheets.

U.S. Pat. No. 6,207,595—describes a dielectric layer fabric material which is made from a cloth member having a low enough content of particulates and a sufficient quantity of resin material to completely encase the cloth member including the particulates, so that the resin material extends beyond the highest protrusions of the cloth member (i.e. the fabric material is thicker and will pass a certain test standard (in '595, the known HAST level A test). Thus, the woven cloth is known to include a quantity of particulates, which term is meant in this patent to include dried film, excess coupler, broken filaments, and gross surface debris. A process is described where a sizing of polyvinyl alcohol, corn starch and a lubricant of oil is applied to the strands of fiber prior to weaving in order to improve the weaving process and minimize breakage of the strands. After weaving, the sizing is removed by a firing step to clean the filaments of lubricants and other materials. However, some sizing may be randomly left behind as particulates. Encasing the woven cloth including the particulates is a quantity of hardened resin material. The resin may be an epoxy resin such as one often used for “FR-4” composites. A resin material based on bismaleimide-triazine (BT) is also described. More preferably, the resin is a phenolic resin material known in the PCB industry. This patent thus requires continuous fibers (those extending across the entire width (or length) of the dielectric layer except for possible inadvertent interruptions caused by drilling of the thru-holes needed in the final product, causing these fibers to become what might be called as “broken.” Fiber strands exposed to the holes may possibly occur with respect to this patent's process.

U.S. Pat. No. 6,184,479—describes a multilayer printed circuit board product which includes a substrate, a first conductive circuit layer, a photosensitive dielectric layer and a second conductive circuit layer which is electrically connected to the first conductive circuit layer through photo-via holes formed in the photosensitive dielectric layer. The second conductive circuit layer includes a wiring area where a plurality of wires are arranged and a pad area to which an external wire is to be connected using thermo-compression bonding. Significantly, to avoid depressing the photosensitive dielectric layer underneath the pad area during the thermo-compression bonding, the thickness of the second conductive circuit layer at least in the pad area, is made greater than that in the wiring area by extending this thickness into the photosensitive dielectric layer.

U.S. Pat. No. 6,025,057—describes a method of fabricating an electronic package having an organic substrate. The substrate is formed of fiberglass and epoxy. In order to additively circuitize the electronic package substrate, an organic polyelectrolyte is deposited onto the organic substrate. A colloidal palladium-tin seed layer is deposited atop the organic polyelectrolyte. This is followed by depositing a photo-imageable polymer atop the seed layer, and photo-lithographically patterning the photo-imageable polymer to uncover portions of the seed layer. The uncovered portions of the seed layer are catalytic to the electro-less deposition of copper. In this way a conductive layer of copper is deposited atop the uncovered seed layer. The organic polyelectrolyte is deposited from an aqueous solution at the pH appropriate for the desired seed catalyst coating, depending on the ionizable character of the particular polyelectrolyte employed

U.S. Pat. No. 5,919,596—describes an admixture which is curable to form a crack resistant, photosensitive poly-cyanurate resist material. Also described is a structure for its use and process of making. The resist can be tailored to be either positively or negatively sensitive to actinic radiation. The resulting thermal and mechanical properties allegedly assure that the cured resist is suitable for use at high temperature, such as in electronic packaging applications.

U.S. Pat. No. 5,798,563—describes an organic chip carrier comprising an organic dielectric layer, a first layer of circuitry disposed on the dielectric layer, an organic conformational coating disposed over the first layer of dielectric and the first layer of circuitry, and a layer of fine line circuitry having line width of about two mil or less and a space between lines of about 1.5 mil or less disposed on the conformational layer. Preferably the dielectric layer is free of woven fiber glass. The conformational coating preferably has a dielectric constant of about 1.5 to about 3.5, and a percent planarization of greater than about 3.5%.

U.S. Pat. No. 5,707,782—describes various photosensitive, dielectric insulating, cross-linkable co-polyester films used as dielectric and as photoresist films for microelectronics circuits which are also suitable for use in producing what are described in this patent as “MCM-L” packages. In various embodiments, there are provided photosensitive, dielectric insulating, cross-linkable co-polyester film forming mixtures for coating onto microelectronics substrate surfaces, a photosensitive oligomer for producing the cross-linkable co-polyesters, and the described “MCM-L” products produced using the cross-linked co-polyesters.

U.S. Pat. No. 5,685,070—describes a printed circuit board (or card) for direct chip attachment that includes at least one power core, at least one signal plane that is adjacent the power core, and PTH's for electrical connection. In addition, a layer of dielectric material is adjacent the power core and a circuitized conductive layer is adjacent the dielectric material, followed by a layer of photosensitive dielectric material adjacent the conductive layer. Photo-developed blind vias for subsequent connection to the power core and drilled blind vias for subsequent connection to the signal plane are provided. Also provided is a process for fabricating the printed circuit board (or card) for accepting the direct chip attachment.

U.S. Pat. No. 5,418,689—describes a PCB product wherein the dielectric substrate can include a thermoplastic and/or thermosetting resin. Thermosetting polymeric materials include epoxy, phenolic base materials, polyimides and polyamides. Examples of some phenolic type materials include copolymers of phenol, resorcinol, and cresol. Examples of some suitable thermoplastic polymeric materials include polyolefins such as polypropylene, polysulfones, polycarbonates, nitrile rubbers, ABS polymers, and fluorocarbon polymers such as polytetrafluoroethylene, polymers of chlorotrifluoroethylene, fluorinated ethylenepropylene polymers, polyvinylidene fluoride and polyhexafluoropropylene. These dielectric materials may be molded articles of the polymers containing fillers and/or reinforcing agents such as glass filled polymers. “FR-4” epoxy compositions that are employed in this patent contain 70-90 parts of brominated polyglycidyl ether of bisphenol-A and 10-30 parts of tetrakis (hydroxyphenyl)ethane tetraglycidyl ether cured with 3-4 parts of dicyandiamide, and 0.2-0.4 parts of a tertiary amine, all parts being parts by weight per hundred parts of resin solids. Another “FR4” epoxy composition may contain about 25 to about 30 parts by weight of a tetrabrominated digylcidyl ether of bisphenol-A having an epoxy equivalent weight of about 350 to about 450; about 10 to about 15% by weight of a tetrabrominated glycidyl ether of bisphenol-A having an epoxy equivalent weight of approximately 600 to about 750 and about 55 to about 65 parts per weight of at least one epoxidized nonlinear novolak having at least 6 terminal epoxy groups; along with suitable curing and/or hardening agents. A still further “FR4” epoxy composition contains 70 to 90 parts of brominated polyglycidyl ether of bisphenol-A and 10 to 30 parts of tetrakis (hydroxyphenyl)ethane tetraglycidyl ether cured with 0.8-1 phr of 2-methylimidazole. Still other “FR4” epoxy compositions employ tetrabromobisphenol-A as the curing agent along with 2-methylimidazole as the catalyst.

U.S. Pat. No. 5,246,817—describes a manufacturing process which consists of the sequential formation of layers using photosensitive dielectric coatings and selective metal deposition procedures. The first layer of the board is formed over a temporary or permanent carrier that may become an integral part of the board. When the carrier is a circuit, the process comprises formation of a dielectric coating over the circuit with imaged openings defining the thru-holes. The imaged openings may be obtained by exposure of a photosensitive dielectric coating to activating radiation through a mask in an imaged pattern followed by development to form the imaged openings. Alternatively, imaging may be by laser ablation in which case, the dielectric material need not be photosensitive. Metal is deposited into the recesses within the dielectric coating to form the conductive thru-holes. Thereafter, an additional layer of dielectric is coated onto the first dielectric layer, imaged in a pattern of circuit lines, and the recesses are then plated with metal. Alternatively, after imaging the first dielectric coating, it may be coated with a second dielectric coating and imaged and the recesses plated with metal to form the thru-holes and circuit lines simultaneously. By either process, the walls of the imaged opening or recesses in the dielectric coating contain metal as it deposits during plating and assures a desired cross-sectional shape of the deposit. Plating desirably fills the entire recess within the imaged photosensitive coating. The process, obviously very complex and costly, is repeated sequentially to form sequential layers of circuits and thru-holes.

U.S. Pat. No. 5,129,142—describes both a structure and a method for making a high density circuit board. Using photosensitive or other dielectric materials over a circuitized power core, vias and lands are opened up, filled with joining metal and aligned with the next level, eliminating a major registration problem in building up a high density composite and reducing the number of steps in the manufacturing process.

U.S. Pat. No. 5,126,192—describes a dielectric material intended to overcome many of the aforementioned concerns relative to known such materials. According to this patent, a resin/silane treated microsphere/carrier structure pre-preg layer is prepared, B-stage cured, and then vacuum laminated. The impregnation mix is prepared by adding a predetermined quantity of microspheres to the resin/solvent mixture sufficient to result in a packing factor of, e.g., about 50% when the solvent is driven off. A low shear mixing technique must be used to avoid damaging the microspheres. Because these are spherical, the microspheres mix in readily and do not increase the viscosity of the solution to a point beyond which impregnation is difficult. The combination of microsphere size and packing factor enables the filled dielectric material to allegedly withstand the heat and pressure cycle of lamination without undergoing breakage of the hollow microspheres. According to this patent, less than 2% microsphere breakage was observed with lamination pressures up to 500 pounds per square inch (PSI). When breakage does occur, the largest microspheres generally collapse first. Hollow silica microspheres containing less than 2% sodium oxide, with 99% by population less than 40 microns in diameter, apparently provided by a company named Grace Syntactics, Inc. under the name “SDT 28”, are described as being acceptable. This same company's “SDT-60” microspheres, sized to 99% by population below 25 microns, are described as the preferred filler. The microspheres are treated with the silane-based coupling agent suitable for use with the specific resin. One coupler described as suitable for these formulations is also mentioned. One coupler mix is described as a combination of vinyl silane and amino silane, for best moisture resistance and acceptable wet dielectric loss performance. Silane resin allegedly binds the filler particles within the resin matrix and minimizes the volume of the interfacial areas between the resin matrix and the micro-spheres. A need to find or develop hollow micro-spheres providing low dielectric loss when blended with epoxy or other thermosetting resins for use in printed wiring boards is necessary. The carrier/reinforcement material in this patent may be any known shell type reinforcement such as glass or polytetrafluoroethylene (PTFE). The carrier fabric selected depends mostly on the properties desired for the finished laminate. These include thickness, Er, CTE, and the intended product application. Carrier materials include woven and non-woven fiber glass and polymer fabrics and mats. Organic films such as polyimide film can also be used. Low Er fabrics such as D-glass, aramids such as Kevlar and Nomex (both registered trademarks of E.I. Dupont de Nemours and Company), poly p-phenylene benzobisthiazole, poly p-phenylene benzobisoxazole, Polyetheretherketone, aromatic polyesters, quartz, S-glass, and the like, can also be used in the formulation. The reinforcement can be in a co-woven or co-mingled form.

Understandably, it is highly desirable to provide a dielectric material as defined herein-below which may form part of a circuitized substrate such as a chip carrier substrate or a PCB which will satisfactorily meet today's many stringent requirements for such materials, thus providing an improvement to same. For example, it is desired to provide a material which, when incorporated within a circuitized substrate product, will assure an accommodating CTE with respect to other elements, e.g., semiconductor chips, of these products. As a further example, it is desired to provide such a material which will meet flammability requirements, will satisfy electrical transmission obligations for signals passing there-through, will assure a low Er, as well as satisfy other mandated requirements. It is further desirable to provide such a material which is relatively easy to work with, in addition to being relatively less expensive to form and utilize compared to some known materials, thereby reducing the overall product cost. Still further, it is very highly desired to provide such a material which may be activated by heat and/or electromagnetic energy in a consistent manner, by including elements therein in optimum proportions sufficient to assure such consistent activation.

It is believed that such a material, and the resulting circuitized substrate products including same, will represent significant advances in the present art. It is further believed that methods of making such circuitized substrates having the material as part thereof will also represent significant advancements in the art.

### OBJECTS AND SUMMARY OF THE INVENTION

It is, therefore, a primary object of the present invention to enhance the circuitized substrate art.

It is another object to provide a new dielectric material which is readily adaptable for use as part of circuitized substrate products to assure many of the features defined herein for such products.

It is still another object of the invention to provide a method of making a circuitized substrate including such a material as part thereof.

In accordance with one embodiment of the invention, there is defined a photosensitive dielectric composition adapted for forming a dielectric film layer for use in a circuitized substrate, this photosensitive dielectric composition comprising an epoxide bearing component including at least one polyepoxide resin curable by electromagnetic radiation, a cyanate ester, a flexibilizer, a nanostructured toughener, a photoinitiator in a predetermined amount by weight of the resin component, and a ceramic filler, the photosensitive dielectric composition forming the dielectric film layer having no solvent therein.

In accordance with another embodiment of the invention, there is defined a heat activated dielectric composition adapted for forming a dielectric film layer for use in a circuitized substrate, this heat activated dielectric composition comprising an epoxide bearing component including at least one polyepoxide resin which is curable by heat, a cyanate ester, a flexibilizer, a nanostructured toughener, a heat activated curing agent for accelerating reaction of the cyanate ester and polyepoxide resin components, and a ceramic filler, the heat activated dielectric composition forming the dielectric film layer having no solvent therein.

In accordance with yet another embodiment of the invention, there is defined a method of making a circuitized substrate comprising forming a first dielectric film layer from a photosensitive dielectric composition including an epoxide bearing component including at least one polyepoxide resin curable by electromagnetic radiation, a cyanate ester, a flexibilizer, a nanostructured toughener, a_photoinitiator in a predetermined amount by weight of the resin component and a ceramic filler, the dielectric film layer having no solvent therein, forming a plurality of openings within this first dielectric film layer and depositing metallurgy within the plurality of openings in a selected manner so as to form electrically conductive features within the dielectric film layer.

In accordance with a further embodiment of the invention, there is provided a method of making a circuitized substrate comprising forming a first dielectric film layer from a heat activated dielectric composition including an epoxide bearing component including at least one polyepoxide resin curable by heat, a cyanate ester, a flexibilizer, a anostructured toughener, a heat activated curing agent for accelerating reaction of said cyanate ester and polyepoxide resin components, and a ceramic filler, the dielectric film layer having no solvent therein, forming a plurality of openings within the first dielectric film layer and depositing metallurgy within the plurality of openings in a selected manner so as to form electrically conductive features within the dielectric film layer.

### BRIEF DESCRIPTION OF THE DRAWINGS

FIGS. 1-6 are side elevational views, in section and on a much enlarged scale, representing the steps utilized to produce a film layer of dielectric material and then forming electrically conductive features thereon and/or therein, to in turn form a circuitized substrate, in accordance with one embodiment of the invention, FIGS. 4-6 being on a larger scale than FIGS. 1-3 for ease of explanation; and

FIG. 7 is a side elevational view, in section and on a much smaller scale than FIGS. 1-3, illustrating an electrical assembly which may utilize one or more of the circuitized substrates defined herein and produced in accordance with the teachings herein.

### BEST MODE FOR CARRYING OUT THE INVENTION

For a better understanding of the present invention together with other and further objects, advantages and capabilities thereof, reference is made to the following disclosure and appended claims in connection with the above-described drawings. It is understood that like numerals may be used to indicate like elements from Figure to Figure.

### DEFINITIONS

By the term “circuitized substrate” as used herein is meant to include substrates including at least one and preferably more organic dielectric layers and at least one and preferably more conductive layers therein/thereon. As understood, the dielectric materials as defined herein are those from compositions which are of the photosensitive (or photoimageable) type as well as those wherein the composition is adapted for being activated by heat. It is also possible in the present invention to combine other known dielectric materials as separate layer components for use in such circuitized substrates having one or more of the invention's dielectric layers as part thereof, if desired. Examples of such other known dielectric materials include fiberglass-reinforced or non-reinforced epoxy resins, polytetrafluoroethylene (Teflon), polyimides, polyamides, cyanate resins, ceramic and other like materials, or combinations thereof. Examples of materials for the conductive layer(s) as used herein include copper or copper alloy, these layers forming power and/or signal planes in the substrate. In the case of the instant invention, since the organic dielectric is a photosensitive material, or is one activated by heat, it is capable of being photo-sensitized or heat-activated to alter certain properties thereof and then developed to reveal the desired circuit pattern(s), including any desired thru holes as defined herein.

By the term “circuitized substrate assembly” as used herein is meant to include at least two of such circuitized substrates in a bonded configuration, one example of bonding being conventional lamination procedures known in the art. One example of such an assembly is a multilayered chip carrier substrate or PCB substrate which includes several dielectric and conductive layers, with the conductive layers formed in an alternating manner relative to the dielectric layers.

By the term “electrical assembly” as used herein is meant at least one circuitized substrate, and preferably several combined to form a circuitized substrate assembly, having one or more electrical components positioned thereon and electrically coupled thereto. One good example of such an assembly is a chip carrier. The term “electrical assembly” as used herein is also meant to include an assembly including a circuitized substrate or substrate assembly (such as a PCB) having another circuitized substrate or substrate assembly (such as a chip carrier substrate) positioned thereon and electrically coupled thereto wherein the positioned substrate assembly in turn has one or more electrical components (defined below) thereon. That is, the term “electrical assembly” as used herein may include the possibility of a chip carrier mounted on a PCB and electrically coupled thereto.

By the term “electrical component” as used herein is meant to include components such as semiconductor chips, resistors, capacitors and the like, which are adapted for being positioned on the external conductive surfaces of such substrates as PCBs and chip carriers, and possibly electrically coupled to other components, as well as to each other, using, for example the PCB's or chip carrier's internal and/or external (surface) circuitry. The circuitized substrates and substrate assemblies formed in accordance with the teachings herein are readily adaptable for having one or more such electrical components positioned thereon and electrically coupled to the internal circuitry thereof, as well as to each other if so desired.

By the term “heat activated” as used herein is meant to define a dielectric material property in which the composition is activated by heat, rather than electromagnetic radiation as defined above. By the term “heat” is meant a temperature within the range of about 140 degrees Celsius (C) to about 220 degrees C., when the composition is in liquid form having the elements listed. Such heat may be applied using a vacuum press, a vacuum industrial oven or other suitable means. When activation occurs, the composition's initiator is activated by the heat and releases active component(s) sufficient to initiate cross-linking of the polyepoxide resin component. Viscosity of the composition at this stage does not change significantly so the thickness desired for the final film layer is controlled using conventional means.

By the term “high speed” as used herein to define the substrate signal speed capabilities is understood to mean signals within a frequency range of from about 3.0 to about 10.0 gigabits per second (GPS) and possibly even faster, as also mentioned above.

By the term “information handling system” as used herein shall mean any instrumentality or aggregate of instrumentalities primarily designed to compute, classify, process, transmit, receive, retrieve, originate, switch, store, display, manifest, measure, detect, record, reproduce, handle or utilize any form of information, intelligence or data for business, scientific, control or other purposes. Examples include personal computers and larger processors such as computer servers and mainframes. Such products are well known in the art and are also known to include PCBs and other forms of circuitized substrates as part thereof, some including several such components depending on the operational requirements thereof.

By the term “photosensitive” as used herein is meant to define a dielectric material property in which the material is sensitive to electromagnetic radiation so as to change one or more properties of the material when the material has been exposed to such radiation. More specifically, the electromagnetic radiation (also referred to as actinic radiation) possesses a wavelength of about 700 nanometers (nm) or less which is capable of directly or indirectly curing (property change) the specified resin component of the invention's resin composition. The term “indirect curing” is meant the condition where curing is initiated, promoted or otherwise mediated by another compound. By way of further example, the dielectric material of this invention may be exposed to such radiation such as through a mask to in turn precisely define a high density pattern of thru holes within the dielectric which are then suitable for being subsequently plated with an appropriate metallurgy so as to render each thru hole electrically conductive. Thru holes (defined below) as treated may then be used to electrically interconnect opposing circuit lines or other elements to form one or more circuit paths within the final substrate product, e.g., a PCB or chip carrier product. It is also to be understood that the term “photosensitive” and “photo-imageable” are often used in an interchangeable manner, such as shown in one or more of the foregoing patents.

By the term “thru hole” as used herein is meant to include three different types of electrically conductive holes formed with one or more dielectric layers of a circuitized substrate or circuitized substrate assembly. As known, multilayer PCB's and chip carrier substrates often provide various conductive interconnections between the various conductive layers of the substrate. For some applications, it is desired that electrical connection be made with almost if not all of the conductive layers. In such a case, thru-holes are typically provided through the entire thickness of the board, in which case these are often also referred to as the aforementioned “plated thru holes” or PTH's. For other applications, it may be desired to also provide electrical connection between the circuitry on one face of the board to a depth of only one or more of the inner circuit layers. These are referred to as “blind vias”, which pass only part way thru (into) the board. In still another case, such multilayered substrates often require internal “vias” which are located entirely within the board's structure and covered by external layering, including both dielectric and conductive. Such internal “vias”, also referred to as “buried vias”, are typically formed within a first circuitized substrate which is then bonded to other substrates and/or dielectric and/or conductive layers to form the final board. Therefore, for purposes of this application, the term “thru hole” is meant to include all three types of such electrically conductive openings, because all may be utilized as part of the substrate and substrate assemblies of the present invention.

### DETAILED DESCRIPTION OF THE EMBODIMENTS

The present invention comprises in one embodiment an improved photosensitive dielectric material which in film form may form part of a circuitized substrate product capable of providing enhanced properties necessary for such products. As defined herein, the dielectric film which forms the base for one or more electrically conductive layers (which may be located thereon and/or therein) possesses improved properties such as reduced thermal expansion, a relatively low dielectric dissipation factor, is relatively free from the presence of residual solvent normally utilized in plasticization of such films, and, equally significant, is relatively free of “phantom vias” (thru holes) often observed in high resolution photosensitive dielectric films used in some circuitized substrates on the market today. In another embodiment, the invention comprises an improved heat activated dielectric material capable of providing substantially similar advantageous properties as those immediately above.

Current photosensitive dielectric films present a unique class of materials that can be used in the circuitized substrate industry as permanent dielectric materials while at the same time providing effective means of interconnecting circuitized layers utilizing the photo mechanism incorporated within such materials. Heat activated dielectric films are believed to also possess similar properties. Some limitations have been seen in the use of these materials, however, during processing thereof or in the final achieved electrical and mechanical properties of the layered material especially since these materials are intended to respond similarly to other, different types of such materials in the industry.

These limitations include the inclusion of a solvent to maintain the flexibility of the film products prior to final substrate incorporation (laminating). For example, the solvent may evaporate at different levels during differing periods of storage as well as handling, thus inconsistently altering the properties of the film. As a result, such film products may have a relatively high dielectric loss. Because of the considered extreme photosensitivity of those of the photosensitive type, the result may be undesirable vias or “phantom” plated vias following plating which in turn may act as shorts in the vertical plane of the circuitized substrate. Such a negative result is also considered possible with respect to heat activated materials. Clearly, this result is highly undesirable when attempting to produce a precise structure having the demanding requirements in today's industry.

As indicated above, a key feature of the present invention is the formation of new and unique dielectric compositions which, when formed, are adapted for use as a dielectric layer in a circuitized substrate. The description now provided will define the elements of this new composition and will also include appropriate background supporting information sufficient to enable the reader to better understand and appreciate the teachings provided herein. The respective elements of the two compositions are defined separated for ease of understanding, with the photosensitive type defined first.

### Photosensitive Dielectric Compositions of the Invention

Examples of suitable photocurable compositions used in the photosensitive compositions of this invention include photosensitive epoxy polymer compositions, photosensitive curable cyanate ester compositions, photosensitive acrylate polymer compositions and photosensitive methacrylate polymer compositions or combinations thereof.

Suitable cyanate ester components include at least one cyanate ester compound (monomer, oligomer, or polymer). Preferably, the cyanate ester component comprises at least one cyanate ester compound (monomer, oligomer, or polymer). More preferably, the cyanate ester component comprises at least one compound having two or more —OCN functional groups per molecule. The molecular weights of suitable cyanate ester compounds are typically about 150 to about 2000. The cyanate ester component preferably includes one or more cyanate ester compounds.

The cyanate esters useful in the compositions of the invention may typically be employed in amounts ranging from about 5% by wt. to about 95% wt. and more typically about 10% by wt. to about 50% by wt. based upon the total weight of the polymerizable components of the composition. The cyanate ester component may be present as a single cyanate ester, preferably having at least two —OCN functional groups per molecule, or as a mixture of cyanate esters, preferably including at least one dicyanate ester. Preferred cyanate esters useful in the present invention include the polyaromatic cyanate esters, such as the dicyanate esters of bisphenols. Especially preferred cyanate esters include the dicyanate esters of bisphenol A, such as the AroCy B-10 cyanate ester monomer, the dicyanate esters of tetramethylbisphenol F, such as AroCy M-10, and the dicyanate esters of bisphenol E, such as AroCy L-10, all available from Huntsman, 10003 Woodloch Forest Drive, The Woodlands Texas 77380. Alternatively, a semisolid dicyanate oligomer of bisphenol A may be employed in conjunction with a cyanate ester of lower viscosity. An especially preferred cyanate ester oligomer is the dicyanate oligomer of bisphenol A, such as the AroCy B-30 semisolid resin, also available from Huntsman.

Epoxy resins suitable in the compositions of this embodiment of the present invention include polyepoxides curable by electromagnetic radiation. Examples of these polyepoxides include polyglycidyl and poly-(b-methylglycidyl)ethers obtainable by reaction of a compound containing at least two free alcoholic hydroxyl and/or phenolic hydroxyl groups per molecule with the appropriate epichlorohydrin under alkaline conditions or, alternatively, in the presence of an acidic catalyst and subsequent treatment with alkali. These ethers may be made from acyclic alcohols such as ethylene glycol, diethylene glycol, and higher poly(oxyethylene) glycols, propane-1,2-diol and poly(oxypropylene) glycols, propane-1,2-diol, butane-1,4-diol, poly(oxytetramethylene) glycols, pentane-1,5-diol, hexane-2,4,6-triol, glycerol, 1,1,1-trimethylolpropane, pentaerythritol, sorbitol, and poly(epichlorohydrin); from cycloaliphatic alcohols such as resorcinol, quinitol, bis(4-hydroxycyclohexyl)methane, 2,2-bis(4-hydroxycyclohexyl)propane, and 1,1-bis(hydroxymethyl)cyclohex-3-ene; and from alcohols having aromatic nuclei, such as N,N-bis(2-hydroxyethyl)aniline and p,p′-bis(2-hydroxyethylamino)diphenylmethane. Also, these may be made from mononuclear phenols, such as resorcinol and hydroquinone, and from polynuclear phenols, such as bis(4-hydroxyphenyl)methane, 4,4-dihydroxydiphenyl, bis(4-hydroxyphenyl sulphone, 1,1,2,2-tetrabis(4-hydroxyphenyl)ethane, 2,2-bis(4-hydroxyphenyl)propane, 2,2-bis(3,5-dibromo-4-hydroxyphenyl)propane, and novolaks formed from the combination of aldehydes, such as formaldehyde, acetaldehyde, and furfuraldehyde, with phenols, such as phenol itself, and phenols substituted on the ring by chlorine atoms or by alkyl groups each containing up to nine carbon atoms such as 4-chlorophenol, 2-methylphenol, and 4-t-butylphenol. Poly(N-glycidyl) compounds include, for example, those obtained by dehydrochlorination of the reaction products of epichlorohydrin with amines containing at least two amino hydrogen atoms, such as aniline, n-butylamine, bis(4-aminophenyl)methane, and bis(4-methylaminophenyl)methane; triglycidyl isocyanurate; and N,N′-diglycidyl derivatives of cyclic alkylene ureas, such as ethyleneurea and 1,3-propyleneureas, and of hydantoins such as 5,5-dimethylhydantoin. Especially preferred epoxy resins include the glycidyl ethers of bisphenol A available from Hexion Specialty Chemicals, 180 East Broad Street Columbus, Ohio 43215, Dow Chemical Co. and Union Carbide Co. Ciba is another source for some of these.

Also useful are halogenated epoxy resins such as the brominated epoxides available from one or more of the sources shown above. Halogenated epoxy resins in combination with other fire retardant materials may be suitable for use as fire retardant additives in the compositions of the present invention.

Various epoxies such as the glycidyl ethers available under the series tradename EPODIL from Pacific Anchor Chemical Corporation (a division of Air Products and Chemicals, Inc.) may be added as epoxy diluents, to reduce the viscosities of the resins of the present invention if desired. Also, phenoxy resins may be used as the film former polymer. A suitable phenoxy polyol resin is available under the trade name “PKHC”, from InChem. Corp., 800 Cel-River Road, Rock Hill, S.C. 29730.

Epoxy compounds are included in the resin compositions of the invention in an amount of from about 15 to 95% by wt., preferably from about 25 to 75% by wt. of the total content of the polymerizable components of the composition.

Suitable polyolefinically unsaturated components of the compositions may include poly(meth)acrylic resins, polyvinyl monomers, and polyunsaturated polyesters solubilized in vinyl monomers. As used herein, the term “(meth) acrylic” is intended to be broadly construed to include acrylic as well as methacrylic compounds, e.g., acrylic esters and methacrylic esters.

In addition, the polyolefinically unsaturated monomer component may comprise one or more low viscosity monoolefinically unsaturated monomers as diluent, but in any event, the olefinically unsaturated monomer component typically comprises at least one polyolefinically unsaturated monomer. As used herein, “polyolefinically unsaturated” means having at least two olefinic double bonds. The polyolefinically unsaturated monomers may be used in amounts of from about 5 to 30% and preferably from about 15 to about 25% by weight of the composition based upon the total content of the polymerizable components of the composition.

Polyacrylates are generally useful, including 1,3-butylene glycol diacrylate, diethylene glycol diacrylate, 1,6-hexanediol diacrylate, neopentylglycol diacrylate, polyethylene glycol diacrylate, tetraethylene glycol diacrylate, methylene glycol diacrylate, pentaerythritol tetraacrylate, tripropylene glycol diacrylate, ethoxylated bisphenol A diacrylate, trimethylolpropane triacrylate, ditrimethylolpropane tetraacrylate, dipenterythritol pentaacrylate, pentaerythritol triacrylate and the corresponding methacrylate compounds. Also useful are reaction products of (meth) acrylic acid and epoxide resins and urethane resins. Some photocurable reaction products of monoethylenically unsaturated acid are known.

Useful (meth) acrylic resins include esters and amides of (meth)acrylic acid as well as comonomers thereof with other copolymerizable monomers. Illustrative esters include methyl acrylate, methyl methacrylate, hydroxyethyl acrylate, butyl methacrylate, octyl acrylate, and 2-epoxyethylacrylate.

Another class of electromagnetic radiation curable resins suitable for use in this embodiment of the compositions of the invention includes vinyl monomers such as styrene, vinyl toluene, vinyl pyrrolidone, vinyl acetate, divinyl benzene, and the like.

A further useful class of electromagnetic (actinic) radiation curable resin materials comprises unsaturated polyesters, solubilized in vinyl monomers, as ordinarily prepared from alpha-beta ethylenically unsaturated polycarboxylic acids and polyhydric alcohols. Preferred polyolefinically unsaturated components include trimethylolpropane trimethacrylate, triethylolpropane triacrylate, dipentaerythritol pentaacrylate, pentaerythritol triacrylate, ethoxylated trimethylolpropane triacrylate, 1,6-hexanediol diacrylate, neopentyl glycol diacrylate, pentaerythritol tetraacrylate, and 1,3-butylene glycol diacrylate. Preferred monoacrylates include cyclohexylacrylate, 2-ethoxyethyl acrylate, 2-methoxy acrylate, benzoyl acrylate, and isobornyl acrylate. Such compounds are available from a variety of sources. For example, a preferred polyacrylate, dipentaerythritol monohydroxypentaacrylate, is available under the tradename SR 399 from Sartomer Company, Inc., 502 Thomas Jones Way, Exton, Pa. 19341.

As defined above, electromagnetic radiation (or actinic radiation) used in this invention means that having a wavelength of about 700 nm or less which is capable, directly or indirectly, of curing the specified resin component of the resin composition. By indirect curing in this context is meant curing under such electromagnetic radiation conditions, as initiated, promoted, or otherwise mediated by another compound.

Accordingly, a photoinitiator is added to the composition in an amount effective to respond to the actinic radiation and to initiate and induce curing of the associated resin, via substantial polymerization thereof. Suitable photoinitiators useful with ultraviolet (UV) actinic radiation curing mono- and polyolefinic monomers include free radical generating UV initiators such as benzophenone and substituted benzophenones, acetophenone and substituted acetophenones, benzoin and its alkyl esters and xanthone and substituted xanthones. Preferred photoinitiators include diethoxy-acetophenone, benzoin methyl ether, benzoin ethyl ether, benzoin isopropyl ether, diethoxyxanthone, chloro-thio-xanthone, azobisisobutyronitrile, N-methyl diethanolaminebenzophenone, and mixtures thereof.

Suitable photo-initiators and sensitizers include cationic initiators which typically generate a Bronsted acid upon exposure to actinic light. Examples of some suitable cationic photo-initiators which generate a Bronsted acid include onium salts and especially group VIA and group VIIA salts such as beryllium, selenonium, sulfonium and iodonium salts. Various suitable photo-initiators are known in the art. The preferred photoacid generators or initiators are triflic acid generators and substituted and unsubstituted diaryl and triarylsulfonium and iodonium salts. Compounds that generate triflic acid include onium salts such as diphenyl-iodonium triflate, di-(t-butyl phenyl) iodonium triflate and triphenylsulfonium triflate and non-ionic compounds such as phthalimide triflate. Mixtures of diphenyl-iodonium triflate, di-(t-butylphenyl)iodonium triflate, or phthalimide triflate may be used.

Aromatic iodonium salts may be employed in accordance with this invention and include diphenyliodonium hexafluoroarsenate, diphenyliodonium hexafluoroantimonate diphenyliodonium hexafluorophosphate, diphenyliodonium trifluoroacetate 4-trifluoromethylphenylphenyliodonium tetrafluoroborate ditolyliodonium hexafluorophosphate di(4-methoxyphenyl)iodonium hexafluoroantimonate diphenyliodonium trifluoromethane sulfonate di(t-butylphenyl iodonium hexafluoroantimonate, di(t-butylphenyl iodonium trifluoromethane sulfonate, (4-methylphenyl)phenyliodonium tetrafluoroborate, di-(2,4-dimethylphenyl)iodonium hexafluoroantimonate, di-(4-t-butylphenyl)iodonium hexafluoroantimonate 2,2′-diphenyliodonium hexafluorophosphate.

A suitable complex triarylsulfonium hexafluoroantimonate salt photoinitiator formerly available under the trade name UVE-1014 from General Electric Company is now available as UVI-6974 from Union Carbide Company. Another is Cyracure 6976 from Dow Chemical Company. Other curing agents useful in the energy polymerizable compositions of the present invention comprise an organometallic compound having metal atoms selected from the elements of Periodic Groups IVB (Ti, Zr, Hf), VB (V, Nb, Ta), VIB (Cr, Mo, W), VIIB (Mn, Tc, Re) and VII (Fe, Ru, Os, Co, Rh, Ir, Ni, Pd, Pt) which are commonly referred to as transition metals.

Visible light initiators include camphoroquinone peroxyester initiators and 9-fluorene carboxylic acid peroxyesters. Particularly preferred photoinitiators include 2-hydroxy-2-methyl-1-phenyl-propan-1-one available as Darocur 1173 from EM Industries, Inc., and 2-benzyl-2-(dimethylamino)-1-[4-(4-morpholinyl)phenyl]-1-butanone available as Irgacure 369 and Irgacure 261 from Ciba.

The photoinitiator usable in these compositions comprises a predetermined percentage by weight of the composition's resin component, and is thus present in an amount sufficient to initiate the photochemical reaction. Usually the amount of photoinitiator is about 0.1 to about 10 percent by weight and preferably about 0.4 to about 1.0 percent by weight based upon the weight of the resin composition on a dry basis.

Compositions employed according to the present invention may also include organic peroxide. Useful peroxides include various peroxyesters such as a-cumyl-peroxy-neodecanoate, 1,1-dimethyl-3-hydroxybutylperoxyneodecanoate, a-cumylperoxyneoheptanoate, t-amylperoxyneodecanoate, t-butylperoxyneodecanoate, t-amylperoxyneodecanoate, t-butylperoxyneodecanoate, t-amylperoxypivalate, t-butylperoxypivalate, 1,1-dimethyl-3-hydroxy-butylperoxy-2-ethylhexanoate, 2,5-dimethyl-2,5-di(2-ethylhexanoylperoxy)hexane, t-amylperoxy-2-ethylhexanoate, t-butylperoxy-2-ethylhexanoate, t-butylperoxyisobutyrate, t-butylperoxymaleic acid, t-butylperoxyacetate, t-amylperoxyacetate and t-amylperoxy-benzoate. Examples of preferred organic peroxides include lauroyl peroxide, t-amylperoxy-2-ethylhexanoate and 1,1-di(butylperoxy)-3,3,5-trimethylhexane. Lauroyl peroxide is available as Alperox-F, t-amylperoxy-2-ethylhexanoate is available as Lupersol 575; and 1,1-di(t-butylperoxy)-2,2,5-trimethylhexane is available as Lupersol 256, all available from Elf Atochem North America, Inc, currently Arkema Inc., 2000 Market Street, Philadelphia, Pa. 19103-3222. Organic peroxides, if used, are generally present in the photosensitive compositions of the invention in an amount of from about 0.2 to about 2% by weight based upon the resin composition.

In addition, the photosensitive compositions of this invention include a predetermined amount (e.g., from about 1-80% by weight) of a filler. The filler is preferably non-conductive, electrically. In one example, the preferred amount of filler is about 40 to about 80% and most preferably about 45 to about 60% by weight based upon the total weight of the resin composition. Suitable fillers include ceramic fillers such as aluminum oxide, 92% alumina, 96% alumina, aluminum nitride, silicon nitride, silicon carbide, beryllium oxide, boron nitride, silicas, silicates, quartz and diamond powder. Typically, the fillers have an average particle size of about 0.1 to about 75 microns, more typically about 0.5 to about 25 microns, and preferably about 0.5 to about 15 microns.

Finally, a surfactant, such as, e.g., a non-ionic surfactant, may be employed. Preferably the surfactant is a fluorinated polyether. A suitable surfactant is available under the trade name “FC-430 Surfactant” from 3M Company.

### Heat Activated Dielectric Compositions of the Invention

The heat activated compositions of this invention include many of the foregoing components used in the photosensitive compositions, but do not require an epoxide bearing component including at least one of the defined polyepoxide resins cured by electromagnetic radiation, while instead including a heat activated curing agent (defined below) designed for accelerating reaction of the composition's cyanate ester. Polyepoxide resins are used as part of these compositions, however, but are those which may be cured by heat (including many of the above), such curing also being accelerated by the cyanate ester reaction. As understood, some of the foregoing polyepoxide resins may be cured by both electromagnetic radiation and heat.

Epoxy resins suitable in the heat activated compositions of the present invention include, as mentioned above, polyepoxides curable by elevated temperatures to the levels defined. Examples of these polyepoxides include polyglycidyl and poly-(b-methylglycidyl)ethers obtainable by reaction of a compound containing at least two free alcoholic hydroxyl and/or phenolic hydroxyl groups per molecule with the appropriate epichlorohydrin under alkaline conditions or, alternatively, in the presence of an acidic catalyst and subsequent treatment with alkali. These ethers may be made from acyclic alcohols such as ethylene glycol, diethylene glycol, and higher poly(oxyethylene) glycols, propane-1,2-diol and poly(oxypropylene) glycols, propane-1,2-diol, butane-1,4-diol, poly(oxytetramethylene) glycols, pentane-1,5-diol, hexane-2,4,6-triol, glycerol, 1,1,1-trimethylolpropane, pentaerythritol, sorbitol, and poly(epichlorohydrin); from cycloaliphatic alcohols such as resorcinol, quinitol, bis(4-hydroxycyclohexyl)methane, 2,2-bis(4-hydroxycyclohexyl)propane, and 1,1-bis(hydroxymethyl)cyclohex-3-ene; and from alcohols having aromatic nuclei, such as N,N-bis(2-hydroxyethyl)aniline and p,p′-bis(2-hydroxyethylamino)diphenylmethane. Also, these may be made from mononuclear phenols, such as resorcinol and hydroquinone, and from polynuclear phenols, such as bis(4-hydroxyphenyl)methane, 4,4-dihydroxydiphenyl, bis(4-hydroxyphenyl sulphone, 1,1,2,2-tetrabis(4-hydroxyphenyl)ethane, 2,2-bis(4-hydroxyphenyl)propane, 2,2-bis(3,5-dibromo-4-hydroxyphenyl)propane, and novolaks formed from the combination of aldehydes, such as formaldehyde, acetaldehyde, and furfuraldehyde, with phenols, such as phenol itself, and phenols substituted on the ring by chlorine atoms or by alkyl groups each containing up to nine carbon atoms such as 4-chlorophenol, 2-methylphenol, and 4-t-butylphenol. Poly(N-glycidyl) compounds include, for example, those obtained by dehydrochlorination of the reaction products of epichlorohydrin with amines containing at least two amino hydrogen atoms, such as aniline, n-butylamine, bis(4-aminophenyl)methane, and bis(4-methylaminophenyl)methane; triglycidyl isocyanurate; and N,N′-diglycidyl derivatives of cyclic alkylene ureas, such as ethyleneurea and 1,3-propyleneureas, and of hydantoins such as 5,5-dimethylhydantoin. Especially preferred epoxy resins include the glycidyl ethers of bisphenol A available from Hexion Specialty Chemicals, 180 East Broad Street Columbus, Ohio 43215, Dow Chemical Co. and Union Carbide Co (currently a subsidiary of Dow Chemical Co.). Ciba is another source for some of these.

Also useful may be halogenated epoxy resins such as the brominated epoxides available from one or more of the sources shown above. Halogenated epoxy resins in combination with other fire retardant materials may be suitable for use as fire retardant additives in the compositions of the present invention.

Various epoxies such as the glycidyl ethers available under the series tradename EPODIL from Pacific Anchor Chemical Corporation (a division of Air Products and Chemicals, Inc.) may be added as epoxy diluents, to reduce the viscosities of the resins of the present invention if desired. Also, phenoxy resins may be used as the film former polymer. A suitable phenoxy polyol resin is available under the trade name “PKHC”, formerly available from Union Carbide Corporation, now available from InChem. Corp., 800 Cel-River Road, Rock Hill, S.C. 29730, USA.

Epoxy compounds are included in the resin compositions of the invention in an amount of from about 15 to 95% by wt., preferably from about 25 to 75% by wt. of the total content of the polymerizable components of the composition.

Suitable polyolefinically unsaturated components of the compositions may include poly(meth)acrylic resins, polyvinyl monomers, and polyunsaturated polyesters solubilized in vinyl monomers. As used herein, the term “(meth) acrylic” is intended to be broadly construed to include acrylic as well as methacrylic compounds, e.g., acrylic esters and methacrylic esters.

In addition, the polyolefinically unsaturated monomer component may comprise one or more low viscosity monoolefinically unsaturated monomers as diluent, but in any event, the olefinically unsaturated monomer component typically comprises at least one polyolefinically unsaturated monomer. As used herein, “polyolefinically unsaturated” means having at least two olefinic double bonds. The polyolefinically unsaturated monomers may be used in amounts of from about 5 to 30% and preferably from about 15 to about 25% by weight of the composition based upon the total content of the polymerizable components of the composition.

Polyacrylates are generally useful, including 1,3-butylene glycol diacrylate, diethylene glycol diacrylate, 1,6-hexanediol diacrylate, neopentylglycol diacrylate, polyethylene glycol diacrylate, tetraethylene glycol diacrylate, methylene glycol diacrylate, pentaerythritol tetraacrylate, tripropylene glycol diacrylate, ethoxylated bisphenol A diacrylate, trimethylolpropane triacrylate, ditrimethylolpropane tetraacrylate, dipenterythritol pentaacrylate, pentaerythritol triacrylate and the corresponding methacrylate compounds. Also useful are reaction products of (meth)acrylic acid and epoxide resins and urethane resins.

Useful (meth)acrylic resins include esters and amides of (meth)acrylic acid as well as comonomers thereof with other copolymerizable monomers. Illustrative esters include methyl acrylate, methyl methacrylate, hydroxyethyl acrylate, butyl methacrylate, octyl acrylate, and 2-epoxyethylacrylate.

These heat activated compositions may also include organic peroxide. Useful peroxides include various peroxyesters such as a-cumyl-peroxy-neodecanoate, 1,1-dimethyl-3-hydroxybutylperoxyneodecanoate, a-cumylperoxyneoheptanoate, t-amylperoxyneodecanoate, t-butylperoxyneodecanoate, t-amylperoxyneodecanoate, t-butylperoxyneodecanoate, t-amylperoxypivalate, t-butylperoxypivalate, 1,1-dimethyl-3-hydroxy-butylperoxy-2-ethylhexanoate, 2,5-dimethyl-2,5-di(2-ethylhexanoylperoxy) hexane, t-amylperoxy-2-ethylhexanoate, t-butylperoxy-2-ethylhexanoate, t-butylperoxyisobutyrate, t-butylperoxymaleic acid, t-butylperoxyacetate, t-amylperoxyacetate and t-amylperoxy-benzoate. Examples of preferred organic peroxides include lauroyl peroxide, t-amylperoxy-2-ethylhexanoate and 1,1-di(butylperoxy)-3,3,5-trimethylhexane. Lauroyl peroxide is available as Alperox-F, t-amylperoxy-2-ethylhexanoate is available as Lupersol 575; and 1,1-di(t-butylperoxy)-2,2,5-trimethylhexane is available as Lupersol 256, all available from Elf Atochem North America, Inc currently Arkema Inc., 2000 Market Street, Philadelphia, Pa. 19103-3222. Organic peroxides, if used, are generally present in the compositions of the invention in an amount of from about 0.2 to about 2% by weight based upon the resin composition.

Catalysts suitable in practicing preferred aspects of the heat activated compositions of this invention are those catalysts capable of accelerating curing of the cyanate resin component. Examples of such catalysts include organo-metal compounds such as lead naphthenate, lead stearate, zinc naphthenate, zinc octylate, tin oleate, stannous laurate, dibutyltin maleate, manganese naphthenate, cobalt naphthenate, acetylacetonate iron, etc.; inorganic metal salts such as SnCl.sub.3, ZnCl.sub.2 and AlCl.sub.3; phenolic compounds such as phenol, xylenol, cresol, resorcinol, catechol and fluoroglycine; and solutions of an organo-metal component including one or more organo-metal compounds, in a phenolic component. In one embodiment, the organo-metal component may be present in an amount of from about 0.01% to about 1.0% of the resin composition on a solids basis. The phenolic component may be present in the resin composition in amounts ranging from about 0.5 to about 10% by weight on a solids basis. Preferred organo-metal salts include copper(II) acetyl acetonate, copper(II) naphthenate, cobalt(II) acetylacetonate, zinc(II) naphthenate, zinc(II) ethylhexanoate, manganese (II) naphthenate, and cyclopentadienyl iron(II) dicarbonyl dimer. Each of these organo-metal salts is readily available from various sources, for example Strem Chemical Corp., Newburyport, Mass. Preferred phenolic compounds include nonyl phenol, bisphenol A, cresol, phenol, and catechol, each of which is readily available from various sources, including Aldrich Chemical Co., Milwaukee, Wis.

In addition, the heat activated compositions, like those which are of the photosensitive type, include a predetermined about (e.g., from about 1-80% by weight) of a filler material. The filler for such applications is preferably non-conductive, electrically. When employed, the preferred amount of filler is about 40 to about 80% and most preferably about 45 to about 60% by weight based upon the total weight of the resin composition. Suitable fillers include ceramic fillers such as aluminum oxide, 92% alumina, 96% alumina, aluminum nitride, silicon nitride, silicon carbide, beryllium oxide, boron nitride, silicas, silicates, quartz and diamond powder. Typically, the fillers have an average particle size of about 0.1 to about 75 microns, more typically about 0.5 to about 25 microns, and preferably about 0.5 to about 15 microns.

Finally, a surfactant, e.g., a non-ionic surfactant, may be employed. Preferably the surfactant is a fluorinated polyether. A suitable surfactant is available under the trade name “FC-430 Surfactant” from 3M Company.

Examples of formulations of the invention's composition are provided below. It is understood that these are examples only, and not meant to restrict the scope of the invention. Abbreviations and names for some components as defined above are provided for ease of explanation purposes. All Examples are capable of being heat activated while Examples III and IV are particularly designed for being photo activated with heat assisted curing.

### Example I

A composition is prepared having about 65.5 grams (gr) of PKHC from Phenoxy Associates, 76 gr of ERL-4221 from Union Carbide, 54.0 gr of Epon SU-8 from Hexion, 102 gr of Epon-1183 also from Hexion, 3.5 gr of UVI-6974 from Union Carbide and 0.06 phr of Ethyl Violet from Aldrich. The solvent content consisting of methyl ethyl ketone, diethylene glycol monomethyl ether acetate, propylene glycol monomethyl ether acetate or combinations is typically greater than 30% and sufficient to provide a composition that is coated on a carrier film using a slot die coating method.

The solvent based composition is coated onto a 1.5 mil thick polyester film “Mylar D” from DuPont using a roll to roll coater and dried at 130 degrees C. for about five minutes to provide a 2.2 mil thick coating on the polyester carrier. The film was subsequently used in fabricating a circuitized substrate test vehicle utilizing a hot roll laminator to place onto a substrate and subsequently processed using normal circuit fabrication processes.

### Example II

A composition is prepared having about 50.4 gr of PKHC from Phenoxy Associates, 81 gr of ERL-4221 from Union Carbide, 42.8 gr of Epon SU-8 from Hexion, 74.5 gr of Epon-1183 also from Hexion, 2.7 gr of UVI-6974 from Union Carbide, 0.045 phr of phthalocyanine green from Aldrich and 284 gr of spherical silica CE Minerals (Teco-sil 20). The solvent content consisting of methyl ethyl ketone, diethylene glycol monomethyl ether acetate, propylene glycol monomethyl ether acetate or combinations is typically greater than 30% and sufficient to provide a composition that is coatable onto a carrier film. The composition was thoroughly mixed using a ceramic ball mill apparatus to produce a very well homogeneous mixture having no silica agglomerates. The photosensitive composition is coated onto a 1.5 mil thick polyester film “Mylar D” from DuPont. The composition is baked at 130 degrees C. for 5 minutes to provide a 2.3 mil thick coating on the polyester carrier. The film is subsequently hot roll laminated onto a substrate for fabricating a circuitized substrate having successive dielectric layers atop each other separated by signal or power planes in between. The layers are cured at temperatures of 180 to 220 degrees C. for 90 to 150 minutes.

### Example III

A photosensitive composition is prepared having about 33.4 gr of PKHC from Phenoxy Associates, 79 gr of ERL-4221 from Union Carbide, 56.0 gr of Epon SU-8 from Hexion, 100 gr of Epon-1183 also from Hexion, 3.6 phr of UVI-6974 from Union Carbide, 0.2 phr of and 349 gr of silica. The solvent content comprising methyl ethyl ketone, diethylene glycol monomethyl ether acetate, propylene glycol monomethyl ether acetate or combinations is greater than 30% and sufficient to provide a composition that is coatable onto a carrier film. The composition is then coated onto a 1.5 mil thick polyester film “Mylar D” from DuPont. The photosensitive composition is baked at 130 degrees C. for 5 minutes to provide a 2.6 mil thick coating on the polyester carrier. The film is subsequently hot roll laminated onto a planar substrate used in evaluation of fabrication a circuitized test pattern panel and imaged by exposing it to 1200 jm/cm2 ultraviolet light. The panel was then baked at about 95-100 degrees C. for about thirty minutes to provide good pattern definition and developed in propylene carbonate or benzyl alcohol.

### Example IV

A photosensitive composition is prepared having about 15 gr of Arocy B-40S from Huntsman, 53.2 gr of PKHC from Phenoxy Associates, 81 gr of ERL-4221 from Union Carbide, 57.0 gr of Epon SU-8 from Hexion, 100 gr of Epon-1183 also from Hexion, 2.6 phr of Irgacure 261 from Ciba, 0.2 phr of Orasol Blue GN from Ciba and 365 gr of Teco-sil 10 from CE minerals and 10 gr of Tuftec (from Asahi Chemicals) in a 30% solids in Toluene solution. The solvent content consisting of methyl ethyl ketone, diethylene glycol monomethyl ether acetate, propylene glycol monomethyl ether acetate or combinations is greater than 30% and sufficient to provide a composition that is coatable onto a carrier film. The photosensitive composition is coated onto a 1.5 mil thick polyester film “Mylar D” from DuPont. The photosensitive composition is baked at 110 degrees C. for ten minutes to provide a 2 mil thick coating on the polyester carrier, removing the solvent. The film was subsequently used in evaluation of fabrication a circuitized test pattern panel and imaged by exposing it to 1300 jm/cm2 ultraviolet light. The panel was then baked at about 95-100 degrees C. for about thirty minutes and developed in propylene carbonate. This additional bake step is accomplished to define the exposed pattern so it will not “wash away”.

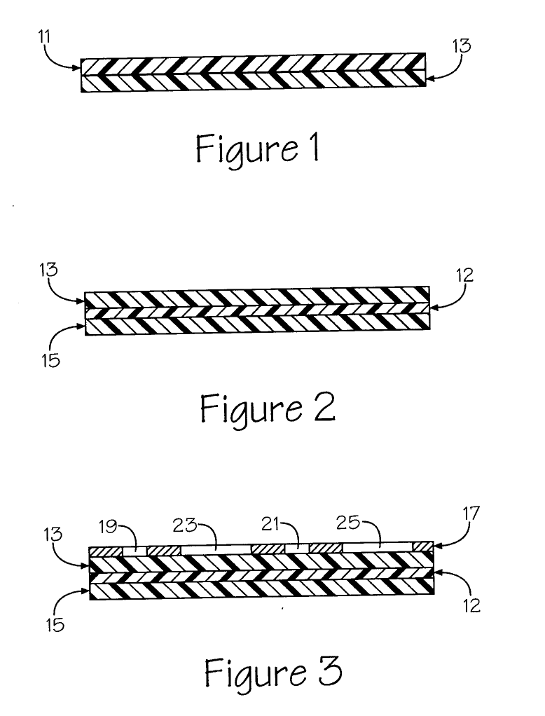

FIGS. 1-6 illustrate the steps of making a circuitized substrate having a photoimageable dielectric film layer as a critical part thereof, in accordance with one embodiment of the invention. It is to be understood that the invention is not limited to this particular methodology in that various alternative steps are possible. It is further understood that these steps in particular involve preparation of a dielectric film product from a photoimageable composition of the type defined herein and do not necessarily involve steps using a heat activated composition. Initially, a photosensitive composition having one of the formulations defined herein is prepared by combining the resin components, photoinitiator(s), and any desired optional ingredient(s), and then combined with an initial solvent, after which it is mixed thoroughly to avoid any agglomeration and thereby assure a fine dispersion composition. In one example, the mixed composition is then filtered through a 5-10 micron filter. Solvent is only employed at this initial step to permit thorough mixing and satisfactory application, with positive results obtained using from about 20 to about 55 percent solvent by weight of the total composition. One suitable example of a solvent for use at this stage is propylene glycol monomethyl ether acetate. Alternatively, the various composition components may be mixed in batch form. When incorporating ceramic components in the composition, sufficient mixing is necessary to assure the desired fine dispersion. Suitable mixers include, for example, vacuum high shear dispersion mixers, ball milling and for low volume quantities, a ceramic ball milling apparatus.

In FIG. 1, the dielectric film is prepared by coating the liquid material 11 from one of the defined compositions onto a support 13, which is preferably optically transparent to the actinic radiation which will eventually be used to image the photosensitive dielectric film. Preferably, the support is a polymeric support, such as one comprised of a suitable polyester material. Suitable examples of such a polyester material include polyethylene terephthalate, available under the trade name Mylar from E.I. DuPont de Nemours & Company, and one sold under the trade name Melinex from Imperial Chemical Industries, now owned by AkzoNobel. The film may also be coated on metallic substrates such as copper, if it is not desired or necessary to expose the dielectric through the support. The photosensitive dielectric is applied to the polymeric support in liquid form or paste form, using conventional application methods such as, for example, wound wire rod draw down technique, reverse roll or slot-die coating techniques. Significantly, the photosensitive dielectric material 11 is now baked to remove substantially all of the solvent; good results have been obtained by air drying typically from about twenty to about forty minutes, or baking at from about 60 degrees C. to about 150 degrees C. for about two to twenty minutes. At this point, the film-support structure, including the material 11 now in a more solidified film (or layer) form 12, may be evaluated for flexibility by manually flexing, bending and creasing. Removal of substantially all of any solvent material within material 11 (now layer 12) is considered very significant because it assures consistency of the layer's electrical and mechanical properties during subsequent processing, as opposed to conditions where unknown quantities of solvent remain within such a layer. Such consistency is considered essential, e.g., to assure substantial prevention of undesirable vias (“phantom” vias), which in turn may act as electrical shorts in the final product, a highly undesirable result which in turn could render the product inoperable.

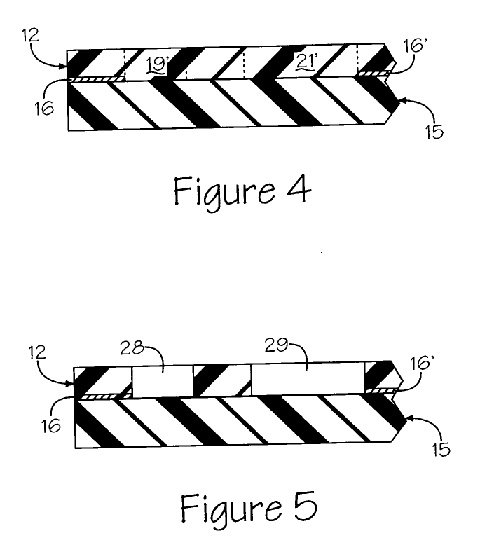

A polymeric cover sheet (not shown in the drawings), also known as an interleaving layer, if present, is now peeled from the photosensitive dielectric film 12, and the photosensitive dielectric film is placed film-side down onto a desired substrate 15, as seen in FIG. 2. If the polymeric support 13 is optically transparent, the polymeric support sheet remains atop the photosensitive dielectric film at this stage. (If the support is not optically transparent, e.g., it is of the aforementioned copper material, then it must be removed and an optically transparent sheet placed atop layer 12). Suitable substrates 15 include, for example, non-circuitized power cores (e.g., a dielectric layer having conductive layers on opposite sides thereof), stiffeners, PCB's, chip carriers, organic and inorganic single chip modules, organic or inorganic multi-chip modules and ceramic carriers. For ease of explanation, substrate 15 is shown as a single layer of dielectric material, such as one well known in the circuitized substrate art, e.g., the aforementioned epoxy resins, polytetrafluoroethylene (Teflon), polyimides, polyamides, cyanate resins, ceramic and other like materials, or combinations thereof. In the enlarged view of FIG. 4, substrate 15 is shown to include conductive pads and/or lines 16 and 16′ thereon (not shown, however, in the smaller scaled FIG. 3, for ease of explanation), as is common in many circuitized substrates, particularly PCB's, chip carriers and the aforementioned power cores. Pads and/or lines 16 and 16′ are preferably copper or copper alloy, also well known conductive materials for circuitized substrates and may be bonded to substrate 15 using conventional plating processes known in the art. Significantly, it is also within the scope of this invention that the underlying substrate 15 designed to host layer 12 may be one similar to that formed in accordance with the teachings of this invention; that is, substrate 15 may include as its dielectric layer a photosensitive or heat activated dielectric material with conductive circuit elements 16 and 16′ formed thereon (as explained in detail below with respect to the product formed from layer 12).

Circuit elements 16 and 16′ may in turn be electrically coupled to other circuitry of substrate 15, as well as to one or more electrical components (not shown) eventually positioned atop the product formed from layer 12. Substrate 15, if a PCB or chip carrier, may further include conductive elements similar to elements 16 and/or 16′ on the opposing undersurface of the substrate, which elements in turn may also be coupled to other circuitry or electrical components. For example, if substrate 15 is a chip carrier, such under elements may in turn be coupled electrically to a host PCB's surface conductive elements, e.g., using solder balls, as is known in the art. If substrate 15 is a power core, it also may include conductive elements on the opposite side thereof which in turn may be coupled to upper elements such as 16 and 16′.

The photosensitive dielectric film layer 12 (and support 13 if bonded to film 12 as shown in FIG. 1) is bonded to hosting substrate 15, preferably by vacuum or hot roll lamination. For example, film 12 may be laminated using a Dynachem, Incorporated Model 730 vacuum laminator having a platen temperature typically from about 55 degrees C. to about 110 degrees C., using about 60 to 130 second dwell time, and from about seven to fifteen second slap-down time. Positive results were obtained at 85-95 degrees C. with 130 second dwell time and an eight second slap-down time. As seen in FIG. 4, such lamination results in the film layer 12 fully covering and thus sealing the upper conductive elements 16 and 16′, layer 12 being of sufficient flexibility to enable such positioning.

In FIG. 3, the photosensitive dielectric film 12 is photo-patterned using conventional exposure techniques by exposing the film through transparent layer 13 to actinic radiation, preferably ultraviolet (UV) light. The photosensitive dielectric film of the compositions defined herein has an advantage, manufacturing-wise, of not needing to be dried prior to exposure to the actinic radiation. Preferably, the film 12 is exposed to the UV light through desired opaque artwork 17 to expose areas corresponding to the position of the desired location of the thru-holes and any associated circuit patterns (i.e., lines and or pads 16 and 16′) for the final substrate product. In one example, the film is exposed to about 150-1200 mJ/cm2 of UV light through artwork 17. A desired UV light source, tool model No 161C (a 4-camera contact tool), is available from Tamarack Scientific Co., Inc., 220 Klug Circle, Corona, Calif. In the specific example of FIG. 3, artwork 17 is shown to include two narrow openings 19 and 21 and two relatively larger (wider) openings 23 and 25. In this example, openings 19 and 21 will serve to define (expose) the underlying portion of photosensitive film layer 12 in which said thru-holes are to be formed, while wider openings 23 and 25 serve to define circuit line and/or pad locations within layer 12. These openings are understood to be representative only because it is well within the scope of this invention to provide many different patterns of thru holes and lines/pads. Again, it is noted that exposure of underlying layer 12 occurs through the optically transparent support layer 13.

Following exposure to the UV light, the artwork 17 and the transparent support 13 are removed, e.g., sequentially peeled away, from the photosensitive dielectric film 12. Such peeling may be accomplished manually or using appropriate peel apparatus known in the circuitized substrate industry. The resulting photosensitive dielectric film 12 is then baked once again, e.g., at about 125 degrees C. for about thirty minutes, to partially cure the photosensitive dielectric film in the areas exposed to the actinic radiation. It is understood with respect to FIG. 3 that these areas are those immediately below the openings 19, 21, 23 and 25.

FIG. 4 represents a much enlarged view of part of FIG. 3, sans artwork 17 and support 13, only depicting the areas of layer 13 below openings 19 and 23. That is, the right half of the FIG. 3 structure is not shown for ease of explanation. These areas are represented by numerals 19′ and 21′ and shown defined by hidden lines. Exposed areas 19′ and 21′ are now developed using propylene carbonate or butyrolactone solution to form a resolution pattern within layer 12. The structure of FIG. 4, with the areas 19′ and 23′ now removed, is then finally cured. A UV “bump”, that is, a second brief exposure to UV light, is utilized for this purpose. In one example, the remaining material of layer 12 is exposed to about 4 J/cm2 at about 250 to 400 nm, thereby finally curing this material. Following this “bump” exposure, yet a third oven bake occurs, e.g., baking at 150 to 200 degrees C. for about sixty minutes. The result is the structure shown in FIG. 5. The open areas once represented by the material of areas 19′ and 21′ are now represented by the numerals 28 and 29, respectively.

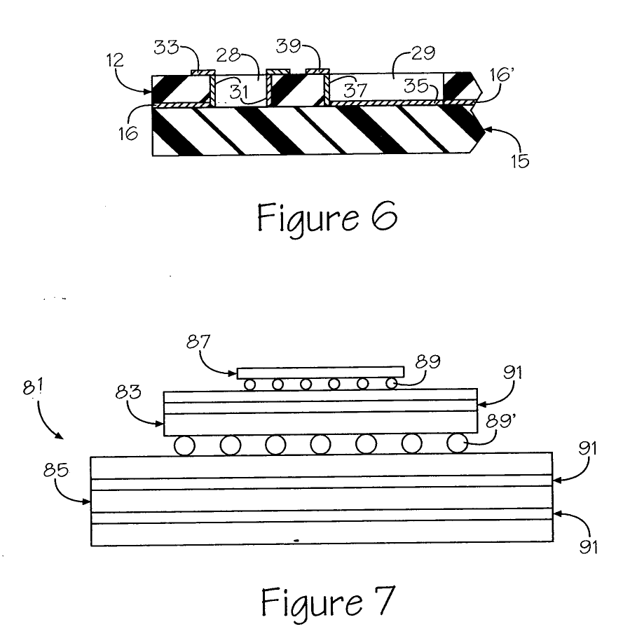

In FIG. 6, various circuit features are deposited onto layer 12, including, as shown, within the openings 28 and 29 once occupied by the material of areas 19′ and 23′. If the opening 28 is to serve as a thru hole, for example, plating is deposited on the sidewalls to form inner layers 31 and may also be deposited across portions of the upper surface of layer 12, thus forming a land 31 about the now electrically conductive opening. The conductive plating is shown as being electrically coupled to the previously deposited line or pad 16, thus forming a circuit including these elements. It is also possible to deposit plating on the upper surface (layer 35) of substrate 15 within opening 29, as well as on one or more sidewalls (layer 37), and on a portion of the upper surface of layer 12 (layer 39) adjacent opening 29, as shown. It is understood that the plating shown in FIG. 6 are representative of many different plating possibilities for this invention and are not limiting of the invention. The primary purpose of depicting those shown in FIG. 6 is to show that thru hole plating as well as circuit line (layer 35) are possible, as well as lands (33) and line or pads 39, all capable of forming various circuit patterns for the final product taught herein.

The circuit features formed herein are preferably of copper or copper alloy and are plated using conventional plating techniques known in the circuitized substrate art. One such process is the Atotech thin panel plating line, wherein copper features having thicknesses of from about 0.3 mils to about 1.5 mils and corresponding widths (if in line form) of about 100 mils are formed (a mil is understood to be 0.001 inch). It is thus seen that highly precise features are possible using the invention's teachings. As further evidence of such preciseness and fine definition, it is possible to form a pattern of thru holes or vias each having a width of about 0.5 mils and spaced only about 6 mils apart. Individual line spacings (distance between adjacent lines) of about 1.5 mils are also possible for the remaining circuitry. To assure proper adhesion between substrate and copper features, pull testing procedures were successful using a tensile tester as defined in IPC-TM-650, method 2.4.8, entitled “Peel Strength of Metallic Clad Laminates.” Following such testing, a conventional solder mask may be applied and conventional finishing steps performed. Thereafter, various electrical components such as, e.g., surface mount components, connectors, resistors, inductors, capacitors, ball grid array packages, wire bond devices and semiconductor chips may be attached to the FIG. 6 structure, e.g, a chip may be coupled to land 33 using a conventional solder ball. As stated in greater detail below, the FIG. 6 structure may also be combined with other substrates to form a much thicker substrate assembly thus having far greater capabilities than that shown in FIG. 6.

As understood from the above, a key attribute of the present invention is a dielectric layer as part of a circuitized substrate which enables the provision of high density arrays of thru-holes and other circuit features such as lines and/or pads within the substrate while preventing electrical shorting or the like between closely spaced, adjacent holes. That is, very highly dense concentrations of relatively narrow (in diameter) thru-holes are capable of being provided in this unique dielectric layer which can then be rendered conductive (typically, plated by suitable metallurgy using convention plating processes) to provide highly dense circuit connections between designated conductive layers (e.g., signal, power and/or ground) within the final substrate incorporating the invention. Significantly, this new dielectric material does not include continuous or semi-continuous fibers such as fiberglass fibers required in so many known dielectric layers, the most well known of same being the aforementioned “FR4” material. The unique material taught herein is able to assure relatively consistent dielectric constants within a relatively thin final layer, both highly desirable if the final product (e.g., chip carrier or PCB) using the substrate is to meet many of today's high density requirements. This material is also able to provide a product which substantially satisfies all of the above stringent requirements mandated for such products.

As further understood from the description herein, a particular use for the circuitized substrate formed herein is as a part within a chip carrier or PCB or other electronic packaging product such as those made and sold by the Assignee of the instant invention, Endicott Interconnect Technologies, Inc. One particular example is a chip carrier sold under the name Hyper-BGA chip carrier (Hyper-BGA being a registered trademark of Endicott Interconnect Technologies, Inc.). The invention is of course not limited to chip carriers or even to higher level PCBs. It is also understood that more than one such circuitized substrate (also referred to in the industry as a “core”, a specific example being what is referred to as a “power core” if the core includes one or more power planes and is thus to serve primarily in this capacity) may be incorporated within such a carrier or PCB, depending on operational requirements desired for the final product. As defined below, this “core” can be readily “stacked up” with other layers, including conductors and dielectric, and bonded together (preferably using conventional PCB lamination processing) to form the multilayered carrier or multilayered PCB. The laminate so formed is then subjected to further processing, including conventional photolithographic processing to form circuit patterns on the outer conductive layers thereof. As described herein, such external patterns can include conductive pads on which conductors such as solder balls can be positioned to connect the structure to other components such as semiconductor chips, PCBs and chip carriers if so desired. The unique teachings of this invention are thus adaptable to a multitude of electronic packaging products. Significantly, the invention thus enables incorporation of the circuitized substrate with its highly dense thru-hole patterns and interconnection capabilities within a larger multilayered structure in which the other layered portions do not possess such densification and operational capabilities. Thus, a “standard” multilayered product can be produced for most of its structure and the unique subcomponent taught herein simply added in as part of the conventional processing of such a “standard.” If the circuitized substrate core is internally positioned, it enables highly dense connections between other, less dense portions of the multilayered product, thus giving said product the unique capabilities of the invention in at least a portion thereof.

FIG. 7 represents one example of an electrical assembly 81 that may be formed using one or more of the circuitized substrates taught herein. As stated, each substrate so formed in accordance with the teachings herein may be utilized within a larger substrate of known type such as a PCB, chip carrier or the like. FIG. 7 illustrates two of these larger components, one being a chip carrier 83 and the other a PCB 85. Obviously, PCB 85 is positioned within and electrically coupled to other elements of an information handling system such as a personal computer, mainframe, server, etc. Chip carrier 83, as shown, is typically positioned on and electrically coupled to an underlying substrate such as PCB 85. Such a carrier also typically has a semiconductor chip 87 mounted thereon and also electrically coupled to the carrier. In the embodiment of FIG. 7, the connections between chip and carrier and between carrier and PCB are accomplished using solder balls 89 and 89′, respectively. Such connections are known in the art and further description is not considered necessary. The significance of FIG. 7 is to show the use of one or more of the circuitized substrates 91 (in phantom) formed using the dielectric compositions of the invention in the chip carrier 83 and PCB 85, thus forming part thereof. Two substrates 91 are shown as used within PCB 85, while only one is shown within carrier 83. As mentioned above, the invention is not limited to the numbers shown. For example, three or more substrates 91, each forming a particular circuitized “core” (e.g., a “power core”) within the PCB, may be utilized to afford the PCB the highly advantageous teachings of the invention.

Thus there have been shown and defined dielectric compositions adapted for forming dielectric layers in a product such as a circuitized substrate, wherein the compositions are free of solvent during the exposure and development phases to define the final layer configuration. Absence of solvent assures consistency of properties in the layer to in turn assure the formation of highly precise conductive features essential in the production of many electronic products of today. The formulations defined herein are possible using many conventional elements and the resulting layers are capable of being subsequently processed using conventional process such as plating.

While there have been shown and described what are at present considered to be the preferred embodiments of the invention, it will be obvious to those skilled in the art that various changes and modifications may be made therein without departing from the scope of the invention as defined by the appended claims.

What is claimed is:

1. A photosensitive dielectric composition adapted for forming a dielectric film layer or use in a circuitized substrate, said photosensitive dielectric composition comprising:
an epoxide bearing component including at least one polyepoxide resin curable by electromagnetic radiation;
a cyanate ester;
a flexibilizer;
a nanostructured toughener;
a photoinitiator in a predetermined amount by weight of the resin component; and
a ceramic filler, said photosensitive dielectric composition forming said dielectric film layer having no solvent therein.

2. The dielectric composition of claim 1 wherein said epoxide bearing component including said at least one polyepoxide resin comprises an amount of about 15 percent to about 65 percent by weight of said composition.

3. The dielectric composition of claim 2 wherein said cyanate ester comprises an amount of about 5 percent to about 35 percent by weight of said composition.

4. The dielectric composition of claim 3 wherein said flexibilizer comprises an amount from about 5 to about 22 percent by weight of said polyepoxide resin of said composition.

5. The dielectric composition of claim 4 wherein said photoinitiator comprises an amount from about 0.1 percent to about 10 percent by weight of said polyepoxide resin of said composition.

6. The dielectric composition of claim 5 wherein said ceramic filler comprises an amount from about 14 to about 56 percent by weight of said polyepoxide resin of said composition and includes particles within the range of from about 0.2 microns to about 5 microns in size.

7. The dielectric composition of claim 6 wherein selected ones of said ceramic particles each have a surface area of from about 0.5 to about 7 m2/gram.

8. The invention of claim 1 wherein said composition is in said dielectric film layer form, said dielectric film layer including at least one conductive layer thereon, said conductive layer comprising copper or a copper alloy.

9. The invention of claim 8 wherein said conductive layer comprises a circuit pattern, said invention comprising a first circuitized substrate.

10. The invention of claim 9 further including at least one additional circuitized substrate bonded to said first circuitized substrate, said bonded circuitized substrates forming a circuitized substrate assembly.

11. The invention of claim 9 further including at least one electrical component positioned on and electrically connected to said circuitized substrate, said circuitized substrate and said at least one electrical component forming an electrical assembly.

12. The invention of claim 11 wherein said electrical assembly comprises a chip carrier.

13. A heat activated dielectric composition adapted for forming a dielectric film layer for use in a circuitized substrate, said heat activated dielectric composition comprising:
an epoxide bearing component including at least one polyepoxide resin curable by heat;
a cyanate ester;
a flexibilizer;
a nanostructured toughener;
a heat activated curing agent for accelerating reaction of said cyanate ester and polyepoxide resin components; and
a ceramic filler, said heat activated dielectric composition forming said dielectric film layer having no solvent therein.

14. The dielectric composition of claim 13 wherein said heat activated curing agent is selected from the group consisting of organo-metal compounds, inorganic metal salts, phenolic compounds, solutions of organo-metal compounds in phenolic compounds and mixtures thereof.

15. The dielectric composition of claim 14 wherein said curing agent comprises from about 0.001 to about 1.0 percent by weight of said polyepoxide resin of said composition.

16. The dielectric composition of claim 13 wherein said epoxide bearing component including said at least one polyepoxide resin comprises an amount of about 15 percent to about 65 percent by weight of said composition.

17. The dielectric composition of claim 16 wherein said cyanate ester comprises an amount of about 5 percent to about 35 percent by weight of said composition.

18. The dielectric composition of claim 17 wherein said flexibilizer comprises an amount from about 5 to about 22 percent by weight of said polyepoxide resin of said composition.

19. The dielectric composition of claim 18 wherein said ceramic filler comprises an amount from about 14 to about 56 percent by weight of said polyepoxide resin of said composition and includes particles within the range of from about 0.2 microns to about 5 microns in size.

20. The dielectric composition of claim 19 wherein selected ones of said ceramic particles each have a surface area of from about 0.5 to about 7 m2/gram.

21. The invention of claim 13 wherein said composition is in said dielectric film layer form, said dielectric film layer including at least one conductive layer thereon, said conductive layer comprising copper or copper alloy.

22. The invention of claim 21 wherein said conductive layer comprises a circuit pattern, said invention comprising a first circuitized substrate.

23. The invention of claim 22 further including at least one additional circuitized substrate bonded to said first circuitized substrate, said bonded circuitized substrates forming a circuitized substrate assembly.

24. The invention of claim 23 further including at least one electrical component positioned on and electrically connected to said circuitized substrate, said circuitized substrate and said at least one electrical component forming an electrical assembly.

25. The invention of claim 24 wherein said electrical assembly comprises a chip carrier.

26. A method of making a circuitized substrate comprising:
forming a first dielectric film layer from a photosensitive dielectric composition including an epoxide bearing component including at least one polyepoxide resin curable by electromagnetic radiation, a cyanate ester, a flexibilizer, a nanostructured toughener; a_photoinitiator in a predetermined amount by weight of the resin component and a ceramic filler, said dielectric film layer having no solvent therein;
forming a plurality of openings within said first dielectric film layer; and
depositing metallurgy within said plurality of openings in a selected manner so as to form electrically conductive features within said dielectric film layer.

27. A method of making a circuitized substrate comprising:
forming a first dielectric film layer from a heat activated dielectric composition including an epoxide bearing component including at least one polyepoxide resin curable by heat, a cyanate ester, a flexibilizer, a nanostructured toughener, a heat activated curing agent for accelerating reaction of said cyanate ester and polyepoxide resin components, and a ceramic filler, said dielectric film layer having no solvent therein;
forming a plurality of openings within said first dielectric film layer; and
depositing metallurgy within said plurality of openings in a selected manner so as to form electrically conductive features within said dielectric film layer.
